(19) United States
(12) Patent Application Publication
(10) Pub. No.: US 2018/0363852 A1
(43) Pub. Date: Dec. 20, 2018

(54) THERMOELECTRIC POWER GENERATING MODULE, AND THERMOELECTRIC POWER GENERATING DEVICE, ANTI-FREEZING VAPORIZER, AND VAPORIZED FUEL GAS LIQUEFACTION PROCESS DEVICE INCLUDING SAME

(71) Applicant: SAMSUNG HEAVY IND. CO., LTD., Seoul (KR)

(72) Inventors: Yong Kyu KIM, Gyeongsangnam-do (KR); Jae-Gwan KIM, Gyeongsangnam-do (KR); Dong Kil LEE, Gyeongsangnam-do (KR); Ho-Ki LEE, Gyeongsangnam-do (KR)

(21) Appl. No.: 15/753,171

(22) PCT Filed: Aug. 20, 2015
(86) PCT No.: PCT/KR2015/008676

§ 371 Date: Feb. 16, 2018

(51) Int. Cl. F17C 7/04; H01L 35/32; F25J 1/00; F25J 1/02

(52) U.S. Cl. CPC F17C 7/04; F25J 2290/72; F25J 1/0025; F25J 1/0225; F17C 2227/0157; F17C 2221/033; F17C 2227/0393; F17C 2205/0352; F17C 2227/0135; F17C 2227/039; F17C 2270/0105; F25J 2230/04; F25J 2230/22; F25J 2230/60; H01L 35/32

(57) ABSTRACT

Provided are a thermoelectric power generation module, a thermoelectric power generation apparatus including the same, an anti-icing vaporization device including the same, and an apparatus for a vaporized fuel gas liquefaction process including the same. The thermoelectric power generation module includes: a pipe through which a fluid flows; and a thermoelectric power generator configured to surround the pipe and to produce power due to a temperature difference between the fluid and outside air.

### TECHNICAL FIELD

The (present) disclosure relates to a thermoelectric power generation module, a thermoelectric power generation apparatus including the same, an anti-icing vaporization device including the same, and an apparatus for a vaporized fuel gas liquefaction process including the same.

### BACKGROUND ART

Since regulations of the International Maritime Organization (IMO) regarding the release of greenhouse gases and various air pollutants have been reinforced in shipbuilding and shipping industries, the use of natural gases as clean energy sources and as fuel gases for a ship, instead of the use of existing fuels like heavy oil and diesel oil, is increasing.

Natural gases that are widely used among fuel gases and regarded as important resources have a main component of methane and are phase-changed into liquefied natural gases (LNG) that are colorless, transparent, and extremely low temperature liquids made by cooling a natural gas to about −162° C. and reducing the natural gas to 1/600 of its volume so that the natural gases may be managed and used.

LNG may be accommodated in an insulated storage tank installed in a ship body and delivered to where it is needed or may be accommodated in a fuel tank and supplied as a fuel gas to an engine of a ship.

In order to use a liquefied fuel gas such as LNG as a fuel gas in the engine of a ship, a process of vaporizing and supplying the liquefied fuel gas is required. These days, a vaporizer that vaporizes the liquefied fuel gas using a temperature difference between a low-temperature liquefied fuel gas and seawater has been used. Such a vaporizer moves the liquefied fuel gas through a transport pipe inside the vaporizer and simultaneously, supplies seawater to an outside of the transport pipe, thereby heating the liquefied fuel gas through the heat-exchanging of the liquefied fuel gas and seawater and phase-changing the liquefied fuel gas into a vaporized fuel gas.

However, due to the temperature difference between the liquefied fuel gas and seawater, icing occurs on the surface of a transport pipe for the liquefied fuel gas adjacent to an inlet of the vaporizer, and due to icing, heat-exchanging of the liquefied fuel gas flowing through the transport pipe and seawater is not smoothly performed, such that the performance of the vaporizer is deteriorated.

Also, when the liquefied fuel gas is accommodated in the storage tank, external heat is continuously transferred to an inside of the storage tank such that an evaporated gas generated by vaporizing the liquefied fuel gas is accumulated in the storage tank. Such evaporated gas may increase an internal pressure of the storage tank, which results in deformation and damage of the storage tank, and vibration of the ship causes a structural problems for the storage tank and the ship while the liquefied fuel gas is delivered.

Thus, in regard to vaporized fuel gas, ways to effectively process and use the evaporated gas or excess vaporized fuel gas that is not supplied to the engine of the ship need to be sought. Also, it is necessary to seek methods of utilizing energy generated due to a temperature difference between an extremely low-temperature liquefied fuel gas and its surroundings while the liquefied fuel gas, the evaporated gas, or the vaporized fuel gas is being managed.

### DISCLOSURE

### Technical Problem

The (present) disclosure is directed to providing a thermoelectric power generation module that is capable of generating power using a temperature difference between an extremely low-temperature fluid and surroundings and effectively using energy, a thermoelectric power generation apparatus including the same, an anti-icing vaporization device including the same, and an apparatus for a vaporized fuel gas liquefaction process including the same.

The (present) disclosure is also directed to providing a thermoelectric power generation module that reduces power required to compress an evaporated gas or vaporized fuel gas and power required to pressurize and deliver a liquefied fuel gas, a thermoelectric power generation apparatus including the same, an anti-icing vaporization device including the same, and an apparatus for a vaporized fuel gas liquefaction process including the same.

### Technical Solution

In accordance with an aspect of the (present) disclosure, a thermoelectric power generation module includes: a pipe through which a fluid flows; and a thermoelectric power generator configured to surround the pipe and to produce power due to a temperature difference between the fluid and outside air.

The thermoelectric power generator may include: a first shell in contact with an outer circumferential surface of the pipe; a second shell spaced a predetermined distance apart from the first shell; and a plurality of thermoelectric elements placed between the first shell and the second shell.

An inert gas may be included between the first shell and the second shell.

Pressure between the first shell and the second shell may be equal to an internal pressure of the pipe.

In accordance with another aspect of the (present) disclosure, a thermoelectric power generation apparatus includes: a compressor configured to compress an evaporated gas of a liquefied fuel gas stored in a storage tank; a thermoelectric power generator configured to generate power using a temperature difference between a fluid passing through the compressor and the liquefied fuel gas supplied from the storage tank; and a vaporizer configured to vaporize the fluid and the liquefied fuel gas that pass through the thermoelectric power generator and to supply the vaporized fluid and liquefied fuel gas to an engine.

The thermoelectric power generation apparatus may further include: a first pipe configured to provide a path through which the fluid moves to the vaporizer and to be in contact with one side surface of the thermoelectric power generator; and a second pipe configured to provide a path through which the liquefied fuel gas moves to the vaporizer and to be in contact with the other side surface of the thermoelectric power generator.

The thermoelectric power generation apparatus may further include: a first pump installed at the second pipe and configured to boost a pressure of the liquefied fuel gas and to deliver the liquefied fuel gas; a second pump installed between the first pump and the vaporizer and configured to boost a pressure of the liquefied fuel gas discharged from the first pump; and a converter configured to convert electricity generated by the thermoelectric power generator and to supply the converted electricity to the compressor, the first pump, and the second pump.

One of the first pipe and the second pipe may surround at least a portion of the other one.

The thermoelectric power generator may be used as a partition wall between the first pipe and the liquefied fuel gas so that the first pipe and the liquefied fuel gas are not in contact with each other.

The vaporizer may include a transport pipe configured to connect, to an outlet part from which a vaporized fuel is drawn, an inlet part into which the fluid and the liquefied fuel gas are introduced, and may provide a space in which seawater heat-exchanged with the transport pipe flows.

In accordance with still another aspect of the (present) disclosure, an anti-icing vaporization apparatus includes: a vaporizer including a transport pipe configured to connect, to an outlet part from which a vaporized fuel gas is drawn, an inlet part into which a liquefied fuel gas is introduced, the vaporizer providing a space in which seawater heat-exchanged with the transport pipe flows, so as to vaporize the liquefied fuel gas into the vaporized fuel gas; a thermoelectric power generator configured to generate power due to a temperature difference between the seawater and a fluid including at least one of the liquefied fuel gas and the vaporized fuel gas that move through the transport pipe; and a heating unit placed on a surface of the inlet part and configured to, using power generated by the thermoelectric power generator, prevent icing of a region of the transport pipe adjacent to the inlet part.

The vaporizer may include a seawater inlet part into which the seawater is introduced and a seawater outlet part from which the seawater is discharged.

The thermoelectric power generator may be placed closer to the inlet part than the outlet part.

The thermoelectric power generator may surround the transport pipe, one side surface of the thermoelectric power generator may be in contact with the transport pipe, and the other side surface of the thermoelectric power generator may be in contact with the seawater.

The heating unit may heat a surface of the inlet part so that the surface of the inlet part is maintained at a predetermined first temperature or higher.

The anti-icing vaporization apparatus may further include a controller configured to output a switch control signal used to input or block power generated by the thermoelectric power generator to or from the heating unit so that a temperature of the surface of the inlet part is maintained between the first temperature and a second temperature that is higher than the first temperature.

In accordance with yet still another aspect of the (present) disclosure, an apparatus for a vaporized fuel gas liquefaction process includes: a compressor configured to compress a vaporized fuel gas so as to form a fluid including a liquefied fuel gas; a driving motor configured to provide a driving force to the compressor; a cooler configured to, using a cooling medium, decrease a temperature of the fluid increased by the compressor; a thermoelectric power generator configured to generate power due to a temperature difference between the fluid having the increased temperature and the cooling medium; and a converter configured to convert power supplied by the thermoelectric power generator and to supply the power to the driving motor.

The apparatus for the vaporized fuel gas liquefaction process may include a plurality of liquefaction process units including the compressor, the driving motor, the cooler, and the thermoelectric power generator, and among the plurality of liquefaction process units, the fluid discharged from the cooler is introduced into the compressor.

The thermoelectric power generator may be placed between a first pipe through which the fluid flows and a second pipe through which the cooling medium flows.

In accordance with yet still another aspect of the (present) disclosure, an apparatus for a vaporized fuel gas liquefaction process includes: a compressor configured to compress a vaporized fuel gas so as to form a fluid including a liquefied fuel gas; a driving motor configured to provide a driving force to the compressor; a first thermoelectric power generator configured to, using a cooling medium, decrease a temperature of the fluid increased by the compressor; a second thermoelectric power generator configured to generate power due to a temperature difference between the fluid having the increased temperature and the cooling medium; and a converter configured to convert power supplied by at least one of the first thermoelectric power generator and the second thermoelectric power generator and to supply the power to the driving motor.

### Advantageous Effects

As described above, in a thermoelectric power generation module, a thermoelectric power generation apparatus including the same, an anti-icing vaporization device including the same, and an apparatus for a vaporized fuel gas liquefaction process including the same, according to (various example) embodiments of the (present) disclosure, power can be produced due to a temperature difference between an extremely low-temperature fluid and air so that power consumption can be reduced.

In the thermoelectric power generation module, the thermoelectric power generation apparatus including the same, the anti-icing vaporization device including the same, and the apparatus for a vaporized fuel gas liquefaction process including the same, according to (various example) embodiments of the (present) disclosure, produced power can be used to compress and re-liquefy an evaporated gas or a vaporized fuel gas, to pressurize a liquefied fuel gas, and to prevent seawater icing of a vaporizer, so that efficient equipment operation is possible.

In the thermoelectric power generation apparatus, the anti-icing vaporization device including the same, and the apparatus for a vaporized fuel gas liquefaction process including the same, according to (various example) embodiments of the (present) disclosure, a pipe can be double-protected, and the outflow of a fluid in the pipe can be delayed even when the pipe is damaged.

### DESCRIPTION OF DRAWINGS

FIG. 1 is a perspective view of a thermoelectric power generation module according to an (example) embodiment of the (present disclosure).

FIG. 2 is a cross-sectional view of a circumference of a pipe of the thermoelectric power generation module of FIG. 1.

FIG. 3 is a cross-sectional view taken in a longitudinal direction of the pipe of thermoelectric power generation module of FIG. 2.

FIG. 4 is a perspective view of a thermoelectric power generation module according to another (example) embodiment of the (present disclosure).

FIG. 5 is a conceptual view of a thermoelectric power generation apparatus according to an (example) embodiment of the (present disclosure).

FIG. 6 is a cross-sectional view of an example of a vaporizer.

FIG. 7 is a perspective view of an example of a thermoelectric element.

FIGS. 8 through 10 are views of various modified examples of a thermoelectric power generator of a thermoelectric power generation apparatus according to an (example) embodiment of the (present disclosure).

FIG. 11 is a cross-sectional view of an anti-icing vaporization apparatus according to an (example) embodiment of the (present disclosure).

FIG. 12 is a perspective view of an example of a thermoelectric semiconductor.

FIG. 13 is a perspective view of an arrangement of a thermoelectric power generator of the anti-icing vaporization apparatus according to an (example) embodiment of the (present disclosure).

FIGS. 14 and 15 are cross-sectional views of an anti-icing vaporization apparatus according to another (example) embodiment of the (present disclosure).

FIG. 16 is a conceptual view of an apparatus for a vaporized fuel gas liquefaction process according to an (example) embodiment of the (present disclosure).

FIGS. 17 through 19 are views of various modified examples of a thermoelectric power generator of an apparatus for a vaporized fuel gas liquefaction process according to an (example) embodiment of the (present disclosure).

FIG. 20 is a conceptual view of an apparatus for a vaporized fuel gas liquefaction process according to another (example) embodiment of the (present disclosure).

### MODES OF THE INVENTION

Hereinafter, exemplary embodiments of the (present) disclosure will be described in detail with reference to the attached drawings. However, it will be easily understood by those skilled in the art that the attached drawings are described to more easily disclose the (present) disclosure and the scope of the (present) disclosure is not limited to the scope of the attached drawings.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

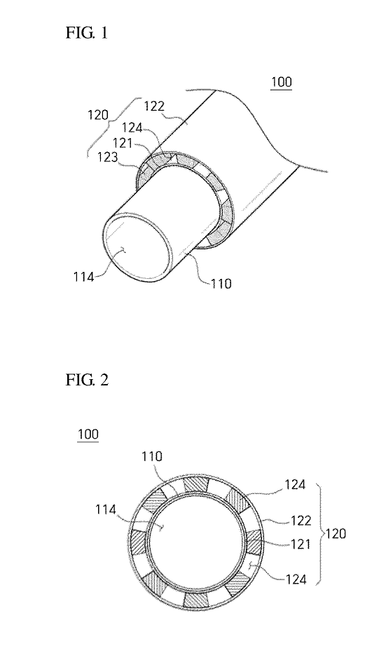

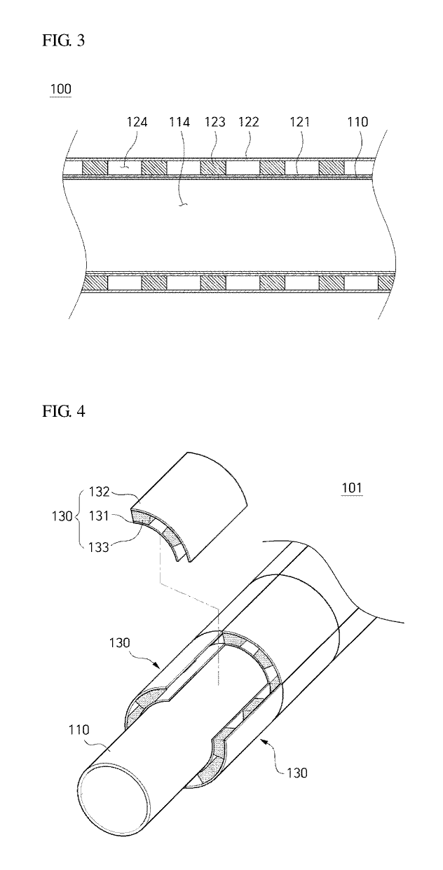

FIG. 1 is a perspective view of a thermoelectric power generation module according to an example embodiment of the (present) disclosure, FIG. 2 is a cross-sectional view of a circumference of a pipe of the thermoelectric power generation module of FIG. 1, and FIG. 3 is a cross-sectional view taken in a longitudinal direction of the pipe of the thermoelectric power generation module of FIG. 2.

Referring to FIGS. 1 through 3, a thermoelectric power generation module 100 according to an example embodiment of the (present) disclosure may include a pipe 110 and a thermoelectric power generator 120.

A fluid may flow through the pipe 110. Here, the fluid may be a liquefied fuel gas, such as a liquefied natural gas (LNG) or a liquefied petroleum gas (LPG). Also, the fluid may be a fluid with a temperature much lower than a room temperature, such as liquefied dioxide.

The pipe 110 may include a single pipe. However, the pipe 110 is not limited to a single pipe but may include a multi-pipe, such as a double or triple pipe. The pipe 110 may be made of a material that may withstand an extremely low-temperature fluid. The material for the pipe 110 may be stainless steel or aluminum (Al).

The thermoelectric power generator 120 may surround the pipe 110 and may produce power due to a temperature difference between the fluid and outside air. For example, when the fluid is a liquefied natural gas of about −163° C. and the outside air is about 0° C. to 30° C., the temperature difference between the fluid and the air may be converted into power. Thermoelectric power generator 120 may include a first shell 121, a second shell 122, and a plurality of thermoelectric elements 123.

The shell 121 may be in contact with an outer circumferential surface of the pipe 110. Also, the first shell 121 may surround the entirety of the outside of the pipe 110. The first shell 121 may have a cylindrical shape to correspond to the outside of the pipe 110. The material for the first shell 121 may be a metal that transfers heat. The first shell 121 may be made of a material that may withstand an extremely low-temperature fluid, like that in the pipe. The material for the first shell 121 may be stainless steel or Al. Also, the material for the first shell 121 may be a metal that may withstand an internal pressure of the pipe 121.

The second shell 122 may be spaced a predetermined distance apart from the first shell 121. Also, when the first shell 121 has a cylindrical shape, the second shell 122 may have a cylindrical shape with a larger outer diameter than that of the first shell 121. A material for the second shell 122 may be a metal that transfers heat, like that of the first shell 121. Also, the thickness of the second shell 122 may be greater than the thickness of the first shell 121 so as to protect the outside of the first shell 121.

The plurality of thermoelectric elements 123 may be placed between the first shell 121 and the second shell 122. Each of the thermoelectric elements 123 may include a low-temperature part that contacts the first shell 121 and a high-temperature part that contacts the second shell 122.

In general, a thermoelectric element has a structure in which N-type and P-type thermoelectric semiconductors are electrically connected to one another in series and thermally connected to one another in parallel, and produces power using thermal energy due to the Seebeck effect. More specifically, when an N-type thermoelectric semiconductor is used in a thermoelectric element, a high-temperature part of the thermoelectric element has a positive pole, and a low-temperature part thereof has a negative pole, such that a potential difference between the high-temperature part and the low-temperature part occurs.

An operating principle of a thermoelectric power generation module according to an example embodiment of the (present) disclosure will be described below.

First, the temperature of the first shell 121 that contacts the pipe 110 may be equal to that of a fluid stored in the pipe 110. The temperature of the low-temperature part of the thermoelectric element 123 that contacts the first shell 121 may be equal to that of the first shell 121. Consequently, the temperature of the fluid in the pipe 110 may be equal to the temperature of the low-temperature part of the thermoelectric element 123.

Meanwhile, the temperature of the second shell 122 may be equal to the temperature of the air outside the second shell 122. The temperature of the high-temperature part of the thermoelectric element 230 that contacts the second shell 122 may be equal to that of the second shell 122.

Thus, the thermoelectric element 123 produces power due to the temperature difference between the high-temperature part and the low-temperature part.

Meanwhile, the plurality of thermoelectric elements 123 may be spaced apart from one another. Thus, a space 124 may be formed between the first shell 121 and the second shell 122.

An inert gas may be included in the space 124 formed between the first shell 121 and the second shell 122. The inert gas may be a gas having relatively low reactivity, such as nitrogen (N), helium (He), or neon (Ne). The inert gas may block heat transfer between the first shell 121 and the second shell 122.

Also, the inert gas may delay the outflow of the fluid of an interior 114 of the pipe 110 when the pipe 110 is damaged.

Meanwhile, pressure between the first shell 121 and the second shell 122 may be equal to an internal pressure of the pipe 110. Thus, even when the pipe 110 is damaged, the outflow of the fluid of the interior 114 of the pipe may be delayed.

In this way, the thermoelectric power generation module 100 according to an example embodiment of the (present) disclosure may produce power using a temperature difference between the fluid and the outdoor air. Also, when the thermoelectric power generation module 100 is installed at a sea structure, energy efficiency of the sea structure can be improved. As power is produced without using fossil energy, environmental pollution can be prevented.

Also, in the thermoelectric power generation module 100 according to an example embodiment of the (present) disclosure, when the pipe 110 is a single pipe and the thermoelectric power generator 120 surrounds the pipe 110 and the pipe 110 is damaged, the outflow of the fluid inside the pipe 110 can be prevented.

FIG. 4 is a perspective view of a thermoelectric power generation module according to another example embodiment of the (present) disclosure. The following elements that are not additionally described in a thermoelectric power generation module according to another example embodiment of the (present) disclosure are similar to those of the above-described thermoelectric power generation module 100 and thus, a detailed description thereof will be omitted.

A plurality of thermoelectric power generators 130 according to another example embodiment of the (present) disclosure may be provided, unlike in the above-described embodiment. That is, the thermoelectric power generators 130 may surround a portion of an outer circumferential surface of the pipe 110. The thermoelectric power generators 130 may include a first shell 131, a second shell 132, and a plurality of thermoelectric elements 133.

Thus, when each of the plurality of thermoelectric power generators 130 is installed at an outside of the pipe 110, the plurality of thermoelectric power generators 130 may surround the entirety of the outside of the pipe 110.

In this way, since a plurality of thermoelectric power generators 130 used in the thermoelectric power generation module 101 according to another example embodiment of the (present) disclosure are provided, it may be easy to install the thermoelectric power generators 130 at the pipe 110. That is, in the thermoelectric power generation module 101 according to another example embodiment of the (present) disclosure, the thermoelectric power generators 130 for a pipe may be additionally installed at an existing pipe without exchanging the existing pipe, unlike in the above-described embodiment.

Also, in the thermoelectric power generation module 101 according to another example embodiment of the (present) disclosure, when a place where a pipe is installed is narrow, the thermoelectric power generators 130 may be installed only at a portion of a pipe where installation is easy.

Hereinafter, a thermoelectric power generation apparatus according to an example embodiment of the (present) disclosure will be described.

FIG. 5 is a conceptual view of a thermoelectric power generation apparatus according to an example embodiment of the (present) disclosure. Referring to FIG. 5, the thermoelectric power generation apparatus includes a compressor 210, a thermoelectric power generator 230, and a vaporizer 240.

As illustrated in FIG. 5, the compressor 210 may compress an evaporated gas of a liquefied fuel gas stored in a storage tank 200 and may supply the evaporated gas compressed by compression.

The evaporated gas stored in the storage tank 200 has a very low temperature, so that a speed at which the evaporated gas is discharged from the storage tank 200 and is moved to the compressor 210 may be slow.

Thus, a heating unit 285 may be placed between the storage tank 200 and the compressor 210 so as to heat the evaporated gas. For example, the heating unit 285 may include a heater or hardwiring. The heating unit 285 is just an example and is not limited thereto.

Also, the thermoelectric power generation apparatus may further include a cooler 220. The cooler 220 may be connected to the compressor 210 so as to reduce the temperature of the compressed evaporated gas.

The evaporated gas may pass through a plurality of compressors 210 and a plurality of coolers 220 and may be introduced into the vaporizer 240.

Compared to the use of a plurality of compressors 210, when a single compressor 210 is used, a compression ratio of the compressor 210 is increased, and the temperature of the compressor 210 after being compressed rises such that compression efficiency may be lowered. Also, the temperature of the compressed evaporated gas by compression is excessively increased such that the compressor 210 may be overheated. Thus, power consumed in the compressor 210 may be increased.

Thus, compression efficiency is increased using the plurality of compressors 210. Also, the temperature of the compressed evaporated gas may be lowered using the plurality of coolers 220 so that power consumed in the compressor 210 can be reduced.

In this case, the temperature of the compressed evaporated gas that passes through the plurality of coolers 220 may be higher than the temperature of the liquefied fuel gas.

The compressed evaporated gas may be moved through a first pipe 281 that connects the coolers 220 to the vaporizer 240, and the liquefied fuel gas may be moved through a second pipe 282 that connects the storage tank 200 to the vaporizer 240.

That is, the first pipe 281 may provide a path through which the compressed evaporated gas is moved to the vaporizer 240, and may be in contact with one side surface of the thermoelectric power generator 230. The second pipe 282 may provide a path through which the liquefied fuel gas is moved to the vaporizer 240, and may be in contact with the other side surface of the thermoelectric power generator 230.

Thus, the thermoelectric power generator 230 may produce power using a temperature difference between the compressed evaporated gas that passes through the compressor 210 and the liquefied fuel gas supplied from the storage tank 200. That is, the temperature of the evaporated gas compressed by compression is higher than the temperature of the liquefied fuel gas so that the thermoelectric power generator 230 may produce power using the temperature difference between the compressed evaporated gas and the liquefied fuel gas.

Also, as illustrated in FIG. 5, while the liquefied fuel gas is moved from the storage tank 200 to the vaporizer 240, the liquefied fuel gas passes through a first pump 250 and a second pump 260.

The first pump 250 may be installed at the second pipe 282 so as to boost the pressure of the liquefied fuel gas and deliver the liquefied fuel gas, and the second pump 260 may be installed between the first pump 250 and the vaporizer 240 and may boost the pressure of the liquefied fuel gas discharged from the first pump 250.

That is, the liquefied fuel gas may be discharged from the storage tank 200 and may flow through the second pipe 282 due to the first pump 250, and the liquefied fuel gas may be boosted by the second pump 260 and may be introduced into the vaporizer 240.

An ME-GI engine of a ship requires the supply of a high-pressure gas of about 150 to 400 bar (absolute pressure).

Thus, when the liquefied fuel gas is supplied to the ME-GI engine, for example, the first pump 250 may be a booster pump, and the second pump 260 may be a high-pressure pump.

That is, the pressure of the liquefied fuel gas stored in the storage tank 200 through the first pump 250 is boosted to an inflow pressure of the second pump 260 and is delivered, and the liquefied fuel gas with the increased pressure may be boosted by the second pump 260 to a pressure required for supply in the ME-GI engine.

The first pump 250 and the second pump 260 are just examples and are not limited thereto, and various types of pumps may be used according to engines.

Meanwhile, the compressed evaporated gas and the liquefied fuel gas may pass through the thermoelectric power generator 230 and then may be combined with each other. The first pipe 281 and the second pipe 282 may be connected to each other so that the compressed evaporated gas passing through the thermoelectric power generator 230 and the liquefied fuel gas can be combined with each other.

Thus, due to the temperature of the compressed evaporated gas, the temperature of the liquefied fuel gas may be increased so that vaporization efficiency of the vaporizer 240 can be that of vaporization of a low-temperature liquefied fuel gas.

The vaporizer 240 may vaporize the compressed evaporated gas that passes through the thermoelectric power generator 230 and the liquefied fuel gas and may supply them to an engine.

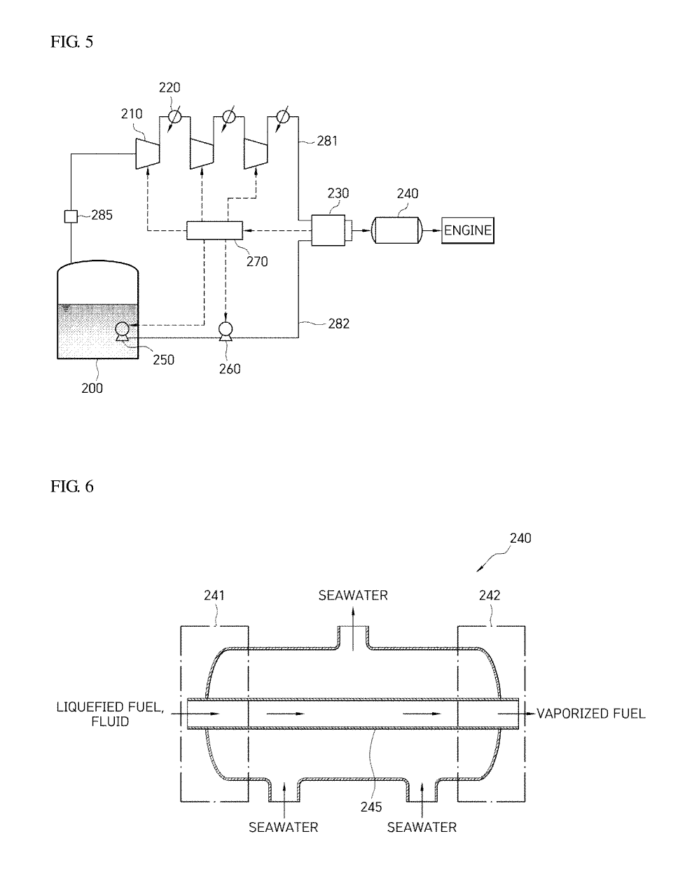

Such a vaporizer 240 will be described in detail with reference to FIG. 6.

The thermoelectric power generation apparatus according to an example embodiment of the (present) disclosure may further include a converter 270.

The converter 270 may convert electricity produced by the thermoelectric power generator 230 and may supply the converted electricity to the compressor 210, the first pump 250, and the second pump 260.

For example, the converter 270 may include a transformer that adjusts a voltage of electricity produced by the thermoelectric power generator 230 to a rated voltage of the compressor 210, the first pump 250, and the second pump 260, or may convert a frequency of electricity supplied to the compressor 210, the first pump 250, and the second pump 260. Conversion of electricity is not limited thereto, and there may be various conversion methods.

Thus, as illustrated in FIG. 5, in the thermoelectric power generation apparatus according to an example embodiment of the (present) disclosure, the evaporated gas is vaporized and is used as a fuel for the engine so that a process of re-liquefying the evaporated gas is not required, and thus a structure of the thermoelectric power generation apparatus can be simplified.

Also, electricity produced by the thermoelectric power generator 230 may be supplied to the compressor 210, the first pump 250, and the second pump 260, so that power can be reduced.

FIG. 6 illustrates a vaporizer of the thermoelectric power generation apparatus according to an example embodiment of the (present) disclosure. As illustrated in FIG. 6, the vaporizer 240 may include an inlet part 241 into which the compressed evaporated gas and the liquefied fuel gas are introduced, an outlet part 242 from which a vaporized fuel is drawn, and a transport pipe 245 that connects the inlet part 241 to the outlet part 242. The vaporizer 240 may provide a space in which seawater heat-exchanged with the transport pipe 245 flows.

As illustrated in FIG. 5, when the compressed evaporated gas and the liquefied fuel gas are combined with each other, due to the temperature of the compressed evaporated gas, the temperature of the liquefied fuel gas increases.

While passing through the transport pipe 245, the compressed evaporated gas and the liquefied fuel gas may be heated by the seawater that flows through the vaporizer 240 and may be changed into the vaporized fuel.

As described above with reference to FIG. 5, the temperature of the liquefied fuel gas rises so that vaporization efficiency of the vaporizer 240 can be improved.

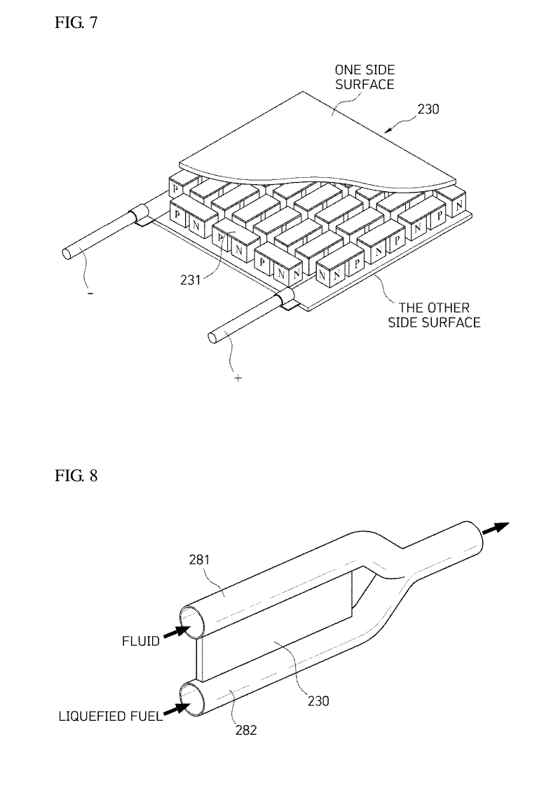

FIG. 7 illustrates an example of a thermoelectric element. As illustrated in FIG. 7, a thermoelectric element 231 that is a semiconductor including N-type and P-type elements may produce power due to the Seebeck effect when heat of a first medium and a second medium having a temperature difference therebetween is in contact with one side surface and the other side surface of the thermoelectric element 231.

The Seebeck effect is a thermoelectric phenomenon in which, when a temperature difference between two metals or semiconductors occurs, a current flows through a closed circuit that connects the two metals or semiconductors to each other.

Thus, the thermoelectric power generator 230 may include thermoelectric elements 231 connected in series or in parallel, and may produce power due to the temperature difference between one side surface and the other side surface of the thermoelectric power generator 230. That is, as illustrated in FIG. 5, power may be produced due to the temperature difference between the compressed evaporated gas and the liquefied fuel gas.

FIGS. 8 through 10 illustrate a thermoelectric power generator of the thermoelectric power generation apparatus according to an example embodiment of the (present) disclosure.

As illustrated in FIG. 8, the thermoelectric power generator 230 may be placed between a first pipe 281 in which the compressed evaporated gas flows and a second pipe 282 in which the liquefied fuel gas flows.

In this case, one side surface of the thermoelectric power generator 230 may be in contact with the first pipe 281, and the other side surface of the thermoelectric power generator 230 may be in contact with the second pipe 282, and the thermoelectric power generator 230 may produce power using the temperature difference between the compressed evaporated gas and the liquefied fuel gas.

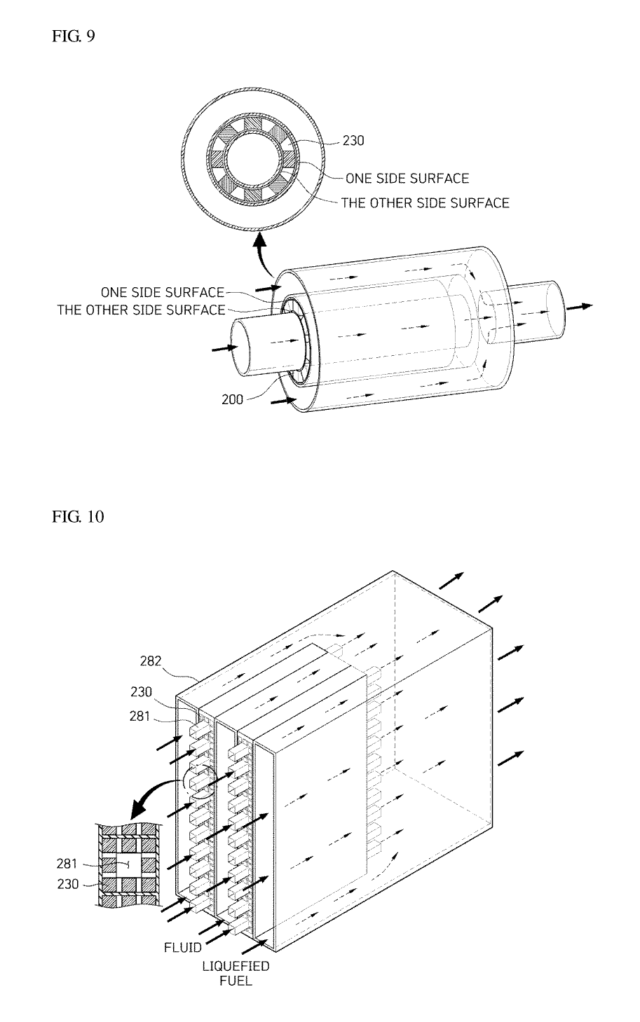

Alternatively, as illustrated in FIG. 9, the thermoelectric power generator 230 may be placed between the first pipe 281 and the second pipe 282, and one of the first pipe 281 and the second pipe 282 may surround at least a portion of the other one of the first pipe 281 and the second pipe 282.

For example, when one side surface of the thermoelectric power generator 230 is in contact with the second pipe 282, the other side surface of the thermoelectric power generator 230 may be in contact with the first pipe 281 in which the compressed evaporated gas flows. Conversely, when one side surface of the thermoelectric power generator 230 is in contact with the first pipe 281, the other side surface of the thermoelectric power generator 230 may be in contact with the second pipe 281 in which the liquefied fuel gas flows.

As illustrated in FIG. 10, the thermoelectric power generator 230 may be used as a partition wall between the first pipe 281 and the liquefied fuel gas so that the first pipe 281 and the liquefied fuel gas are not in contact with each other.

As illustrated in FIG. 10, the thermoelectric power generator 230 surrounds the first pipe 281 so that the first pipe 281 and the liquefied fuel gas may not be in direct contact with each other.

In contrast, when the first pipe 281 and the liquefied fuel gas are in direct contact with each other, heat-exchanging between the first pipe 281 and the liquefied fuel gas is performed so that a temperature difference between the compressed evaporated gas that flows through the first pipe 281 and the liquefied fuel gas can be reduced.

Thus, since the amount of electricity produced by the thermoelectric power generator 230 can be reduced, the first pipe 281 and the liquefied fuel gas need to be separated from each other.

The electricity produced by the thermoelectric power generator 230 illustrated in FIGS. 8 through 10 may be converted by the converter 270 previously described in FIG. 5.

The electricity converted by the converter 270 may be supplied to the compressor 210, the first pump 250, and the second pump 260 so that power consumed in the compressor 210, the first pump 250, and the second pump 260 can be reduced.

In the thermoelectric power generation apparatus according to an example embodiment of the (present) disclosure, the evaporated gas generated in the liquefied fuel storage tank 200 is compressed, cooled, then introduced into the vaporizer 240, and can be used as a fuel for the engine so that a process of converting the evaporated gas into a liquefied fuel gas is omitted and the structure of the thermoelectric power generation apparatus can be simplified.

Also, electricity may be produced due to the temperature difference between the compressed evaporated gas and the liquefied fuel gas, and the produced electricity may be supplied to the compressor 210, the first pump 250, and the second pump 260 so that power can be reduced.

Hereinafter, an anti-icing vaporization apparatus according to an example embodiment of the (present) disclosure will be described.

Referring to FIG. 6, in a general vaporizer 240, a liquefied fuel gas introduced into an inlet part 241 is heat-exchanged with seawater, which is a heat-exchanging medium, and then is changed into a vaporized fuel gas in a gaseous state, and the vaporized fuel gas in the gaseous state may be discharged from an outlet part 242 of the vaporizer 240.

While the liquefied fuel gas is vaporized by the vaporizer 240, icing may occur in a region of the transport pipe 245 adjacent to the inlet part 241 due to the liquefied fuel gas and the seawater. When icing occurs in the region of the transport pipe 245 adjacent to the inlet part 241, heat-exchanging between the liquefied fuel gas that passes through the transport pipe 245 and the seawater is not smoothly performed, such that the performance of the vaporizer 240 may be lowered.

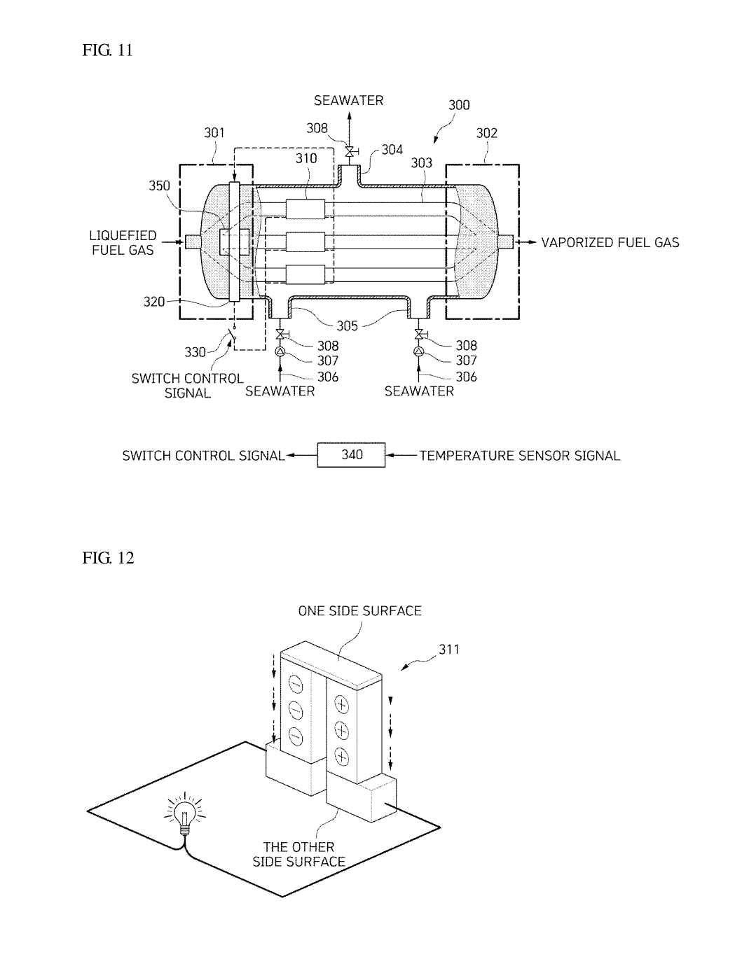

FIG. 11 illustrates an anti-icing vaporization apparatus according to an example embodiment of the (present) disclosure. As illustrated in FIG. 11, the anti-icing vaporization apparatus according to an example embodiment of the (present) disclosure includes a vaporizer 300, a thermoelectric power generator 310, and a heating unit 320.

The vaporizer 300, as a device for vaporizing a liquefied fuel gas into a vaporized fuel gas, may include a transport pipe 303 configured to connect, to an outlet part 302 from which the vaporized fuel gas is drawn, an inlet part 301 into which the liquefied fuel gas is introduced, and may provide a space in which seawater heat-exchanged with the transport pipe 303 flows.

The thermoelectric power generator 310 may produce power due to a temperature difference between seawater and a fluid including at least one of the liquefied fuel gas and the vaporized fuel gas that move through the transport pipe 303.

While passing through the transport pipe 303, the liquefied fuel gas may be changed into the vaporized fuel gas in a gaseous state from a liquid state. Thus, going toward the inlet part 301, more of the liquefied fuel gas than the vaporized fuel gas is present in the fluid, and going toward the outlet part 302, a larger amount of the vaporized fuel gas than the liquefied fuel gas may be present in the fluid.

The heating unit 320 may be placed on the surface of the inlet part 301 and may prevent, using power produced by the thermoelectric power generator 310, icing of a region of the transport pipe 303 adjacent to the inlet part 301.

The heating unit 320 may include a heater or hardwiring. However, the heating unit 320 is just an example and is not limited thereto.

The vaporizer 300 of the anti-icing vaporization apparatus according to an example embodiment of the (present) disclosure may include a seawater inlet part 305 into which seawater as a heat-exchanging medium is introduced, and may include a seawater outlet part 304 from which the seawater is discharged.

Because the seawater is heat-exchanged with the transport pipe 303 inside the vaporizer 300 and is then discharged, a seawater movement line 306 may include a pump 307 for movement of seawater and a valve 308 for adjusting the flow rate of the seawater.

As illustrated in FIG. 11, the thermoelectric power generator 310 may surround the transport pipe 303, one side surface of the thermoelectric power generator 310 may be in contact with the transport pipe 303, and the other side surface of the thermoelectric power generator 310 may be in contact with the seawater.

The thermoelectric power generator 310 may be placed closer to the inlet part 301 than to the outlet part 302. This is because the temperature of the fluid is increased going toward the outlet part 302 from the inlet part 301 while the fluid passing through the transport pipe 303 is heat-exchanged with the seawater.

That is, because the temperature difference between the transport pipe 303 and the seawater is decreased going toward the outlet part 302, power produced by the thermoelectric power generator 310 can be reduced.

In contrast, when the thermoelectric power generator 310 is placed closer to the inlet part 301 than to the outlet part 302, a relatively large amount of power can be produced.

The heating unit 320 may heat the surface of the inlet part 301 so that the surface of the inlet part 301 is maintained at a predetermined first temperature or higher due to power input from the thermoelectric power generator 310. In this way, when the surface of the inlet part 301 is heated, heat may be transferred to the region of the transport pipe 303 adjacent to the inlet part 301 so that icing of the region of the transport pipe 303 adjacent to the inlet part 301 can be prevented.

That is, icing that disturbs heat-exchanging between the fluid flowing through the transport pipe 303 and the seawater is prevented so that heat-exchanging between the fluid and the seawater is smoothly performed, and thus the performance of the vaporizer 300 can be improved.

The anti-icing vaporization apparatus according to an example embodiment of the (present) disclosure may further include a controller 340.

The controller 340 may output, to a switch 330, a switch control signal used to input or block power produced by the thermoelectric power generator 310 to or from the heating unit 320 so that the temperature of the surface of the inlet part 301 is maintained between the first temperature and a second temperature that is higher than the first temperature.

Meanwhile, a temperature sensor 350 may be installed at the surface of the inlet part 301. A temperature sensor signal that indicates the temperature of the surface of the inlet part 301 and is measured by the temperature sensor 350 may be input to the controller 340.

When the temperature of the surface of the inlet part 301 is lower than the predetermined first temperature, the controller 340 may output, to the switch 330, the switch control signal used to electrically connect the thermoelectric power generator 310 to the heating unit 320 so that power produced by the thermoelectric power generator 310 can be input to the heating unit 320.

When the temperature of the surface of the inlet part 301 is higher than the second temperature, the controller 340 may output, to the switch 330, the switch control signal used to electrically block the thermoelectric power generator 310 and the heating unit 320 so that power produced by the thermoelectric power generator 310 is not input to the heating unit 320.

That the temperature of the surface of the inlet part 301 is higher than the second temperature means that power input to the heating unit 320 is excessive, and thus there is a possibility that the heating unit 320 may be damaged.

That is, the controller 340 may maintain the temperature of the surface of the inlet part 301 between the first temperature and the second temperature, thereby preventing icing of the region of the transport pipe 303 adjacent to the inlet part 301 and preventing the heating unit 320 from being damaged due to overheating.

FIG. 12 illustrates an example of a thermoelectric semiconductor. As illustrated in FIG. 12, when heat of the first medium and heat of the second medium, between which there is a temperature difference, is moved through one side surface and the other side surface of the thermoelectric semiconductor 311, the thermoelectric semiconductor 311 may produce power via the Seebeck effect.

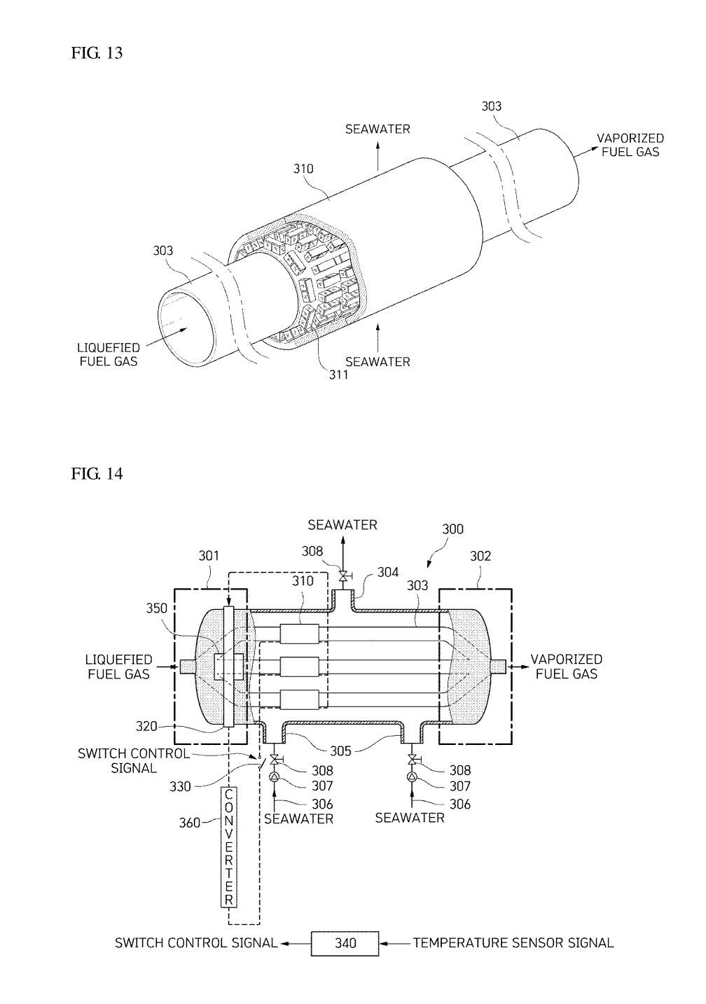

FIG. 13 is a perspective view of a thermoelectric power generator of an anti-icing vaporization apparatus according to an example embodiment of the (present) disclosure. As illustrated in FIG. 13, thermoelectric semiconductors 311 may be connected to one another in series or in parallel so that the thermoelectric power generator 310 can be formed.

The thermoelectric power generator 310 surrounds the transport pipe 303. In this case, one side surface of the thermoelectric power generator 310 may be in contact with the transport pipe 303, and the other side surface of the thermoelectric power generator 310 may be in contact with the seawater.

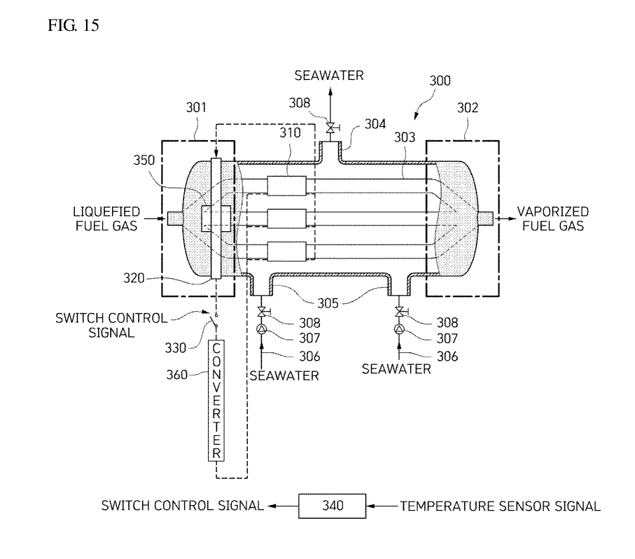

FIGS. 14 and 15 illustrate an anti-icing vaporization apparatus according to another example embodiment of the (present) disclosure, i.e., various embodiments in which the arrangement of a switch 330, a thermoelectric power generator 310, and a converter 360 is modified. As illustrated in FIGS. 14 and 15, when power produced by the thermoelectric power generator 310 is not appropriate for use in the heating unit 320, the converter 360 may be used.

The converter 360 may convert power produced by the thermoelectric power generator 310 into power appropriate to be supplied to the heating unit 320. The converter 360 may be changed in various ways according to an installation environment of the anti-icing vaporization apparatus, according to an example embodiment of the (present) disclosure.

For example, when a voltage of electricity produced by the thermoelectric power generator 310 is not suitable for a rated voltage of the heating unit 320, the converter 360 may include a transformer for adjusting the voltage of the thermoelectric power generator 310 to the rated voltage of the heating unit 320.

As illustrated in FIGS. 14 and 15, the switch 330 may be disposed between the thermoelectric power generator 310 and the converter 360 or between the converter 360 and the heating unit 320. Alternatively, power produced by the thermoelectric power generator 310 may be input to or blocked from the heating unit 360 using a switch control signal output from the controller 340.

The anti-icing vaporization apparatus according to an example embodiment of the (present) disclosure in the above-described drawings may prevent icing of a region of a transport pipe 303 adjacent to an inlet part 301 of the vaporizer 300 and may improve the performance of the vaporizer 300.

Also, the anti-icing vaporization apparatus according to the (present) disclosure prevents icing using power produced due to a temperature difference between seawater and a liquefied fuel gas, so that icing can be prevented without additional power consumption, and the anti-icing vaporization apparatus according to the (present) disclosure prevents icing without the use of the seawater so that a problem of corrosion of the vaporizer 300 can be solved.

Hereinafter, an apparatus for a vaporized fuel gas liquefaction process according to an example embodiment of the (present) disclosure will be described.

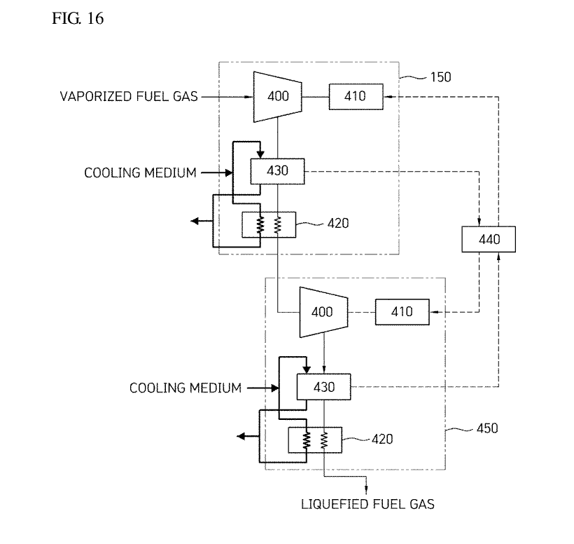

FIG. 16 illustrates an apparatus for a vaporized fuel gas liquefaction process according to an example embodiment of the (present) disclosure. Referring to FIG. 16, the apparatus for the vaporized fuel gas liquefaction process according to an example embodiment of the (present) disclosure includes a compressor 400, a driving motor 410, a cooler 420, a thermoelectric power generator 430, and a converter 440.

The compressor 400 may compress a vaporized fuel gas so as to form a fluid including a liquefied fuel gas. Both the pressure and temperature of the fluid may higher than that of the vaporized fuel gas due to compression.

The cooler 420 may decrease, using a cooling medium, the temperature of the fluid increased by the compressor 400. The temperature of the fluid may be decreased and lastly may be changed into the liquefied fuel gas.

The thermoelectric power generator 430 may produce power due to a temperature difference between the fluid having the increased temperature and the cooling medium. That is, the thermoelectric power generator 430 may produce power using the temperature difference between the fluid and the cooling medium used in the vaporized fuel gas liquefaction process. The cooling medium may be additionally supplied to the cooler 420 and the thermoelectric power generator 430.

The converter 440 may convert power supplied from the thermoelectric power generator 430 so as to supply the power to the driving motor 410. The converter 440 may be changed in various ways according to an installation environment of the apparatus for the vaporized fuel gas liquefaction process, according to an example embodiment of the (present) disclosure.

For example, when a voltage of electricity produced by the thermoelectric power generator 430 is not suitable for the rated voltage of the driving motor 410, the converter 440 may include a transformer for adjusting the voltage of the thermoelectric power generator 430 to the rated voltage of the driving motor 410.

The driving motor 410 may provide a driving force to the compressor 400. The driving motor 410 may use power produced by the thermoelectric power generator 430, excluding the power supplied for the liquefaction process, so that the total power consumption in the apparatus for the vaporized fuel gas liquefaction process can be reduced.

The apparatus for the vaporized fuel gas liquefaction process according to an example embodiment of the (present) disclosure includes a plurality of liquefaction process units 450 including the compressor 400, the driving motor 410, the cooler 420 and the thermoelectric power generator 430, and among the plurality of liquefaction process units 450, the fluid discharged from the cooler 420 may be introduced into the compressor 400.

When the plurality of liquefaction process units 450 are used, power required to compress the vaporized fuel gas can be reduced compared to a case where one liquefaction process unit 450 is used, and compression efficiency can be improved and cooling efficiency can also be increased.

Also, the thermoelectric power generator 430 included in the plurality of liquefaction process units 450 produces power and supplies the power to the driving motor 410 so that power consumed in the plurality of liquefaction process units 450 can be reduced.

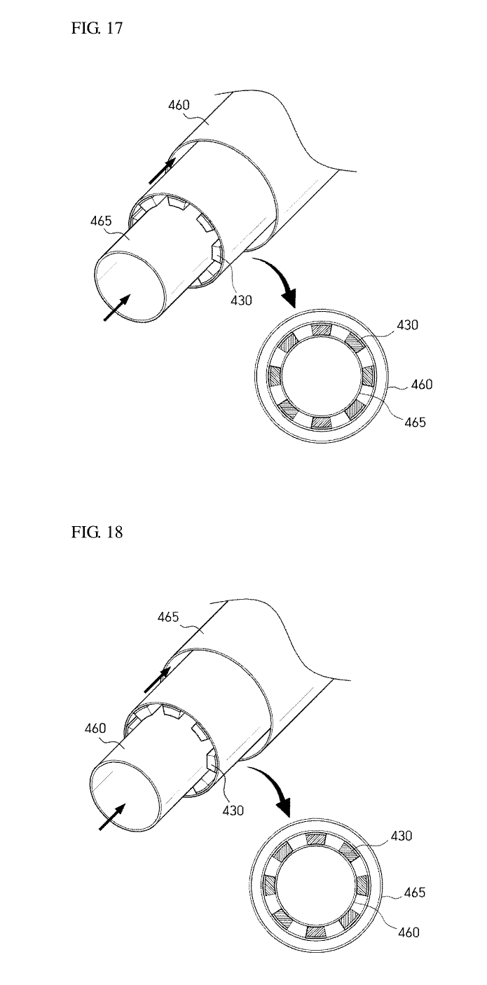

FIGS. 17 through 19 include a perspective view and a cross-sectional view of various modified examples of a thermoelectric power generator of an apparatus for a vaporized fuel gas liquefaction process according to an example embodiment of the (present) disclosure.

As illustrated in FIGS. 17 and 18, the thermoelectric power generator 430 may be placed between a first pipe 460 through which the fluid flows and a second pipe 465 through which the cooling medium flows. One of the first pipe 460 and the second pipe 465 may surround at least a portion of the other one.

For example, as illustrated in FIG. 17, when the first pipe 460 surrounds the second pipe 465, one side surface of the thermoelectric power generator 430 may be in contact with the fluid, and the other side surface of the thermoelectric power generator 430 may be in contact with the second pipe 465.

In contrast, as illustrated in FIG. 18, when the second pipe 465 surrounds the first pipe 460, one side surface of the thermoelectric power generator 430 may be in contact with the cooling medium, and the other side surface of the thermoelectric power generator 430 may be in contact with the first pipe 460.

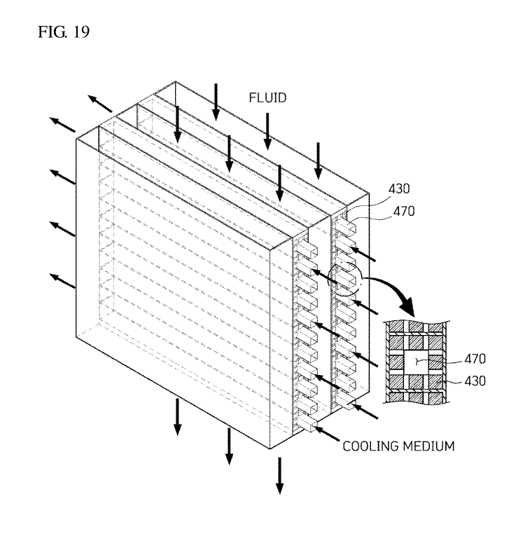

FIG. 19 illustrates a thermoelectric power generator different from that of FIGS. 17 and 18. As illustrated in FIG. 19, one side surface of the thermoelectric power generator 430 may be in contact with the fluid passing through the compressor 400, and the other side surface of the thermoelectric power generator 430 may be in contact with a medium pipe 470 through which the cooling medium flows.

The thermoelectric power generator 430 may be placed between the medium pipe 470 and the fluid and used as a partition wall therebetween so that the medium pipe 470 and the fluid may not be in contact with each other. In contrast, when the medium pipe 470 is in contact with the fluid, the amount of power generation may be reduced or no power may be produced. Thus, the medium pipe 470 and the fluid need to be separated from each other. In the embodiment of the (present) disclosure, because the thermoelectric power generator 430 serves as the partition wall, the medium pipe 470 and the fluid may be separated from each other without any additional configuration.

The medium pipe 470 may be installed to cross a direction in which the flow flows.

As illustrated in FIGS. 17 through 19, the thermoelectric power generator 430 may produce power using a temperature difference between one side surface of the thermoelectric power generator 430 and the other side surface of the thermoelectric power generator 430.

The power produced by the thermoelectric power generator 430 may be supplied to the driving motor 410 so as to drive the compressor 400, so that power consumption of the apparatus for the vaporized fuel gas liquefaction process can be reduced.

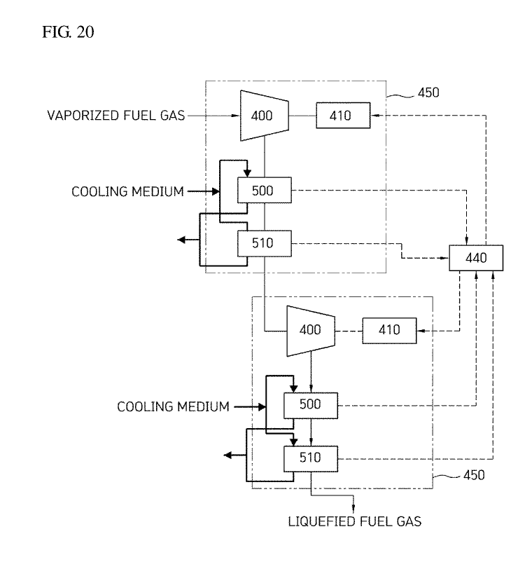

FIG. 20 illustrates an apparatus for a vaporized fuel gas liquefaction process according to another example embodiment of the (present) disclosure. As illustrated in FIG. 20, the apparatus for the vaporized fuel gas liquefaction process according to another example embodiment of the (present) disclosure includes a compressor 400, a driving motor 410, a first thermoelectric power generator 500, a second thermoelectric power generator 510, and a converter 440.

The compressor 400 may compress a vaporized fuel gas so as to form a fluid including a liquefied natural gas, and the driving motor 410 may provide a driving force to the compressor 400.

The first thermoelectric power generator 500 may decrease, using a cooling medium, the temperature of the fluid increased by the compressor 400, and the second thermoelectric power generator 510 may produce power due to a temperature difference between the fluid having the increased temperature and the cooling medium.

The first thermoelectric power generator 500 and the second thermoelectric power generator 510 may include a plurality of thermoelectric elements. Because each of the thermoelectric elements produces power through heat-exchanging due to a temperature difference between one side surface and the other side surface of the thermoelectric element, heat of the fluid is delivered to the cooling medium so that the fluid can be cooled.

Thus, the first thermoelectric power generator 500 may decrease, using the cooling medium, the temperature of the fluid increased by the compressor 400, like in the cooler 420 included in the apparatus for the vaporized fuel gas liquefaction process according to an example embodiment of the (present) disclosure.

Although both the first thermoelectric power generator 500 and the second thermoelectric power generator 510 may produce power using the temperature difference between the fluid and the cooling medium, power produced by the first thermoelectric power generator 500 and power produced by the second thermoelectric power generator 510 may be equal to or different from each other depending on the temperature difference between the fluid and the cooling medium.

In order to supply the converted power to the driving motor 410, The converter 440 may convert power supplied by at least one of the first thermoelectric power generator 500 and the second thermoelectric power generator 510 as. The converter 440 may be changed in various ways according to an installation environment of the apparatus for the vaporized fuel gas liquefaction process, according to another example embodiment of the (present) disclosure.

For example, when a voltage of electricity produced by the first thermoelectric power generator 500 and the second thermoelectric power generator 510 is not suitable for a rated voltage of the driving motor 410, the converter 440 may include a transformer for adjusting the voltage of the first thermoelectric power generator 500 and the second thermoelectric power generator 510 to the rated voltage of the driving motor 410.

The apparatus for the vaporized fuel gas liquefaction process according to another example embodiment of the (present) disclosure may supply the power produced by the first thermoelectric power generator 500 and the second thermoelectric power generator 510 to the driving motor 410 so that power consumption in the apparatus for the vaporized fuel gas liquefaction process can be reduced.

The apparatus for the vaporized fuel gas liquefaction process according to another example embodiment of the (present) disclosure includes a plurality of liquefaction process units 450 including the compressor 400, the driving motor 410, the first thermoelectric power generator 500 and the second thermoelectric power generator 510, and among the plurality of liquefaction process units 450, the fluid discharged from the first thermoelectric power generator 500 may be introduced into the compressor 400.

The use of the plurality of liquefaction process units 450 has been described above in the embodiment of the (present) disclosure, and thus a detailed description thereof will be omitted.

As illustrated in FIGS. 17 and 18, at least one of the first thermoelectric power generator 500 and the second thermoelectric power generator 510 may be placed between a first pipe 460 through which the fluid flows and a second pipe 465 through which the cooling medium flows.

One of the first pipe 460 and the second pipe 465 may surround at least a portion of the other one.

For example, as illustrated in FIG. 17, when the first pipe 460 surrounds the second pipe 465, one side surface of at least one of the first thermoelectric power generator 500 and the second thermoelectric power generator 510 may be in contact with the fluid, and the other side surface of at least one of the first thermoelectric power generator 500 and the second thermoelectric power generator 510 may be in contact with the second pipe 465.

In contrast, as illustrated in FIG. 18, when the second pipe 465 surrounds the first pipe 460, one side surface of at least one of the first thermoelectric power generator 500 and the second thermoelectric power generator 510 may be in contact with the cooling medium, and the other side surface of at least one of the first thermoelectric power generator 500 and the second thermoelectric power generator 510 may be in contact with the first pipe 460.

As illustrated in FIG. 19, one side surface of at least one of the first thermoelectric power generator 500 and the second thermoelectric power generator 510 may be in contact with the fluid, and the other side surface of at least one of the first thermoelectric power generator 500 and the second thermoelectric power generator 510 may be in contact with the medium pipe 470 through which the cooling medium flows.

At least one of the first thermoelectric power generator 500 and the second thermoelectric power generator 510 may be placed between the medium pipe 470 and the fluid and used as a partition wall therebetween so that the medium pipe 470 and the fluid may not be in contact with each other. A function of the partition wall has been described above in the embodiment of the (present) disclosure, and thus a description thereof will be omitted.

In the apparatus for the vaporized fuel gas liquefaction process according to an example embodiment of the (present) disclosure in the above-described drawings, the compressor 400 and the cooler 420 have a multi-stage connection to each other so that the vaporized fuel gas can be compressed and cooled in steps and changed into the liquefied fuel gas.

Also, in the apparatus for the vaporized fuel gas liquefaction process according to the (present) disclosure, power produced using the temperature difference between the fluid and the cooling medium is supplied to the vaporized fuel gas driving motor 410 of the compressor 400 so that power consumed in the liquefaction process can be reduced.

While the invention has been shown and described with reference to certain exemplary embodiments thereof, it will be understood by those skilled in the art that various changes in form and details may be made therein without departing from the spirit and scope of the invention as defined by the appended claims.

1. A thermoelectric power generation module comprising:
a pipe through which a fluid flows; and
a thermoelectric power generator configured to surround the pipe and to produce power due to a temperature difference between the fluid and outside air.

2. The thermoelectric power generation module of claim 1, wherein the thermoelectric power generator comprises:
a first shell in contact with an outer circumferential surface of the pipe;
a second shell spaced a predetermined distance apart from the first shell; and
a plurality of thermoelectric elements placed between the first shell and the second shell.

3. The thermoelectric power generation module of claim 2, wherein an inert gas is include between the first shell and the second shell.

4. The thermoelectric power generation module of claim 3, wherein pressure between the first shell and the second shell is equal to an internal pressure of the pipe.

5. A thermoelectric power generation apparatus comprising:
a compressor configured to compress an evaporated gas of a liquefied fuel gas stored in a storage tank;
a thermoelectric power generator configured to generate power using a temperature difference between a fluid passing through the compressor and the liquefied fuel gas supplied from the storage tank; and
a vaporizer configured to vaporize the fluid and the liquefied fuel gas that pass through the thermoelectric power generator and to supply the vaporized fluid and liquefied fuel gas to an engine.

6. The thermoelectric power generation apparatus of claim 5, further comprising:
a first pipe configured to provide a path through which the fluid moves to the vaporizer and to be in contact with one side surface of the thermoelectric power generator; and
a second pipe configured to provide a path through which the liquefied fuel gas moves to the vaporizer and to be in contact with the other side surface of the thermoelectric power generator.

7. The thermoelectric power generation apparatus of claim 6, further comprising:
a first pump installed at the second pipe and configured to boost a pressure of the liquefied fuel gas and to deliver the liquefied fuel gas;
a second pump installed between the first pump and the vaporizer and configured to boost a pressure of the liquefied fuel gas discharged from the first pump; and
a converter configured to convert electricity generated by the thermoelectric power generator and to supply the converted electricity to the compressor, the first pump, and the second pump.

8. The thermoelectric power generation apparatus of claim 6, wherein one of the first pipe and the second pipe surrounds at least a portion of the other one.

9. The thermoelectric power generation apparatus of claim 6, wherein the thermoelectric power generator is used as a partition wall between the first pipe and the liquefied fuel gas so that the first pipe and the liquefied fuel gas are not in contact with each other.

10. The thermoelectric power generation apparatus of claim 5, wherein the vaporizer comprises a transport pipe configured to connect, to an outlet part from which a vaporized fuel is drawn, an inlet part into which the fluid and the liquefied fuel gas are introduced, and provides a space in which seawater heat-exchanged with the transport pipe flows.

11. An anti-icing vaporization apparatus comprising:
a vaporizer comprising a transport pipe configured to connect, to an outlet part from which a vaporized fuel gas is drawn, an inlet part into which a liquefied fuel gas is introduced, and providing a space in which seawater heat-exchanged with the transport pipe flows, so as to vaporize the liquefied fuel gas into the vaporized fuel gas;
a thermoelectric power generator configured to generate power due to a temperature difference between the seawater and a fluid including at least one of the liquefied fuel gas and the vaporized fuel gas that move through the transport pipe; and
a heating unit placed on a surface of the inlet part and configured to, using power generated by the thermoelectric power generator, prevent icing of a region of the transport pipe adjacent to the inlet part.

12. The anti-icing vaporization apparatus of claim 11, wherein the vaporizer comprises a seawater inlet part into which the seawater is introduced and a seawater outlet part from which the seawater is discharged.

13. The anti-icing vaporization apparatus of claim 11, wherein the thermoelectric power generator is placed closer to the inlet part than the outlet part.

14. The anti-icing vaporization apparatus of claim 11, wherein the thermoelectric power generator surrounds the transport pipe, one side surface of the thermoelectric power generator is in contact with the transport pipe, and the other side surface of the thermoelectric power generator is in contact with the seawater.

15. The anti-icing vaporization apparatus of claim 11, wherein the heating unit heats a surface of the inlet part so that the surface of the inlet part is maintained at a predetermined first temperature or higher.

16. The anti-icing vaporization apparatus of claim 11, further comprising a controller configured to output a switch control signal used to input or block power generated by the thermoelectric power generator to or from the heating unit so that a temperature of the surface of the inlet part is maintained between the first temperature and a second temperature that is higher than the first temperature.

17. An apparatus for a vaporized fuel gas liquefaction process, comprising:
a compressor configured to compress a vaporized fuel gas so as to form a fluid including a liquefied fuel gas;
a driving motor configured to provide a driving force to the compressor;
a cooler configured to, using a cooling medium, decrease a temperature of the fluid increased by the compressor;
a thermoelectric power generator configured to generate power due to a temperature difference between the fluid having the increased temperature and the cooling medium; and
a converter configured to convert power supplied by the thermoelectric power generator and to supply the power to the driving motor.

18. The apparatus for the vaporized fuel gas liquefaction process of claim 17, wherein the apparatus for the vaporized fuel gas liquefaction process comprises a plurality of liquefaction process units comprising the compressor, the driving motor, the cooler, and the thermoelectric power generator, and among the plurality of liquefaction process units, the fluid discharged from the cooler is introduced into the compressor.

19. The apparatus for the vaporized fuel gas liquefaction process of claim 17, wherein the thermoelectric power generator is placed between a first pipe through which the fluid flows, and a second pipe through which the cooling medium flows.

20. An apparatus for a vaporized fuel gas liquefaction process, comprising:
a compressor configured to compress a vaporized fuel gas so as to form a fluid including a liquefied fuel gas;
a driving motor configured to provide a driving force to the compressor;
a first thermoelectric power generator configured to, using a cooling medium, decrease a temperature of the fluid increased by the compressor;
a second thermoelectric power generator configured to generate power due to a temperature difference between the fluid having the increased temperature and the cooling medium; and
a converter configured to convert power supplied by at least one of the first thermoelectric power generator and the second thermoelectric power generator and to supply the power to the driving motor.
